(19) United States
(12) Patent Application Publication
(10) Pub. No.: US 2015/0022731 A1
(43) Pub. Date: Jan. 22, 2015

(54) TOUCH SCREEN PANEL AND FABRICATING METHOD THEREOF

(71) Applicant: Samsung Display Co., Ltd., Yongin-city (KR)

(72) Inventors: Sung-Ku KANG, Yongin-city (KR); Jung-Yun KIM, Yongin-city (KR); Mi-Ae PARK, Yongin-city (KR)

(73) Assignee: Samsung Display Co., Ltd., Yongin-city (KR)

(21) Appl. No.: 14/157,839

(22) Filed: Jan. 17, 2014

(30) Foreign Application Priority Data
Jul. 17, 2013 (KR) 10-2013-0084292

(51) Int. Cl. G06F 3/041; C23C 16/513; C23C 16/40

(52) U.S. Cl. CPC G06F 3/041; C23C 16/407; C23C 16/513
USPC 349/12; 427/58

(57) ABSTRACT

A method of fabricating a touch screen panel includes forming an insulating layer on a substrate. A pattern is formed in the insulating layer. The pattern includes concave portions and convex portions. Sensing electrodes are formed in at least a portion of the concave portions.

### CROSS-REFERENCE TO RELATED APPLICATION

This application claims priority from and the benefit of Korean Patent Application No. 10-2013-0084292, filed on Jul. 17, 2013, which is incorporated by reference for all purposes as if set forth herein.

### BACKGROUND

1. Field

Exemplary embodiments relate to touch screen panels and methods of fabricating the same.

2. Discussion

A touch screen panel is an input device that enables a user to input instructions through one or more touches and/or gestures, either of which may be performed using, for example, an object, a finger, etc. Conventional touch screen panels are typically formed in association with a “front” surface of a display device, and, thereby, configured to detect and convert at least one contact position into an electrical input signal. It is noted that the contact position may correspond to a direct or “near” contact between the object, finger, etc., and the touch screen panel. In this manner, instruction content that, for instance, may be selected via the one or more touches and/or gestures at or near the point of contact may be input as an electrical input signal to, for example, an electronic device associated with the touch screen panel.

The relative intuitiveness of touch screen panels has sparked adoption in various electronic devices, such as, for example, automated teller machines, computers, digital assistants, gaming consoles, kiosks, mobile phones, navigational devices, etc. As such, touch screen panels are typically coupled to an outer surface of a display device, such as a liquid crystal display device, an organic light emitting display device, etc. In this manner, touch screen panels are generally highly transparent and relatively thin. To this end, as flexible display device technology advances, a concomitant desire for flexible touch screen panels has also arisen.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a touch screen panel and a method of manufacturing the same.

Additional aspects will be set forth in the detailed description which follows and, in part, will be apparent from the disclosure, or may be learned by practice of the inventive concept.

According to exemplary embodiments, a method of fabricating a touch screen panel, includes: forming an insulating layer on a substrate; forming a pattern in the insulating layer, the pattern including concave portions and convex portions; and forming sensing electrodes in at least a portion of the concave portions.

According to exemplary embodiments, a touch screen panel, includes: a flexible substrate; an insulating layer disposed on the flexible substrate, the insulating layer including a pattern of trenches from therein; and sensing electrodes at least partially formed in the trenches.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept and are incorporated in and constitute a part of this specification, illustrate exemplary embodiments of the inventive concept, and together with the description serve to explain principles of the inventive concept.

FIG. 1 is a schematic plan view of a touch screen panel, according to exemplary embodiments.

FIG. 2 is a partial enlarged view of sensing electrodes of the touch screen panel of FIG. 1, according to exemplary embodiments.

FIG. 3A is an enlarged perspective view of connecting portions of the sensing electrodes of FIG. 2, according to exemplary embodiments.

FIG. 3B is a sectional view of the connecting portions taken along sectional line I-I′ of FIG. 3A, according to exemplary embodiments.

FIGS. 4A to 4D are respective sectional views of various concavo-convex patterns, according to exemplary embodiments.

FIGS. 5A to 5F are respective sectional views of the touch screen panel of FIG. 1 at various stages of manufacture, according to exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

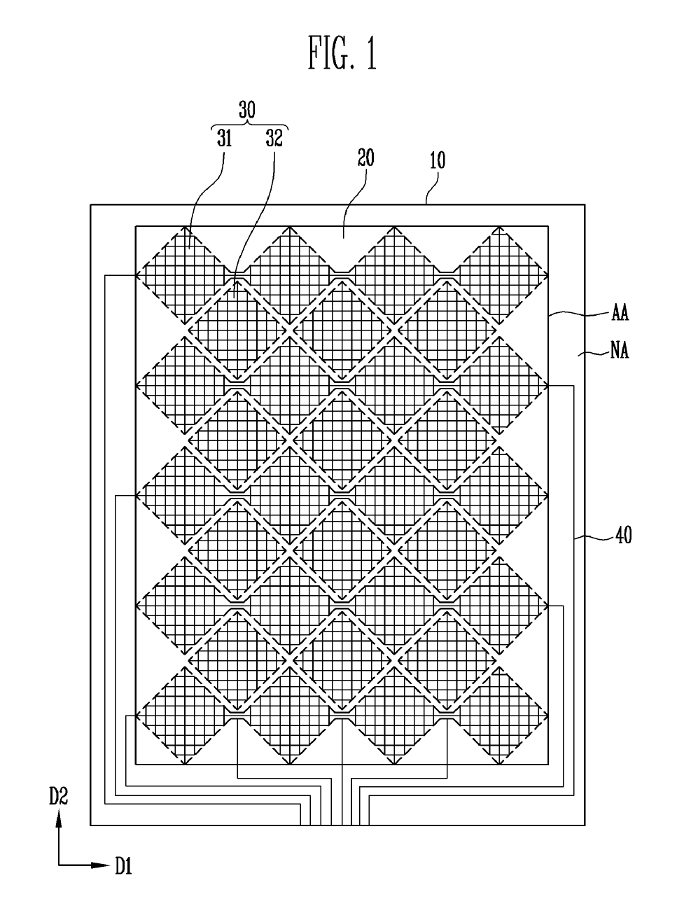

FIG. 1 is a schematic plan view of a touch screen panel, according to exemplary embodiments.

Referring to FIG. 1, the touch screen panel may include a substrate 10, an insulating layer 20, sensing electrodes 30, and outer lines (e.g., transmission lines) 40. Although specific reference will be made to this implementation, it is also contemplated that the touch screen panel may embody many forms and include multiple and/or alternative components.

According to exemplary embodiments, the substrate 10 may be divided into an active area AA and a non-active area NA. The active area may be overlapped with a display area. To this end, the sensing electrodes 30 may be formed in the active area AA so that a touch input may be enabled via the active area AA. The non-active area NA may be positioned at the outside of the active area AA, such as surrounding the active area AA. The outer lines 40 may be formed at least in the non-active area NA. It is noted that the non-active area NA may be a light-shielding area overlapped with a non-display area. In this manner, the non-active area NA may surround the active area AA in which an image is displayed via the display area.

The substrate 10 may form a window on an upper substrate of a display panel or a front surface of the touch screen panel. In this manner, the substrate 10 may be made of any suitable material having sufficient flexibility, high thermal resistance, and high chemical resistance. For example, the substrate 10 may be a thin-film substrate formed of one or more materials, such as polyethylene terephthalate (PET), polyimide (PI), polyethylene (PE), polycarbonate (PC), polyamide (PA), poly(methyl methacrylate) (PMMA), triacetylcellulose (TAC), polyethersulfone (PES), and/or the like.

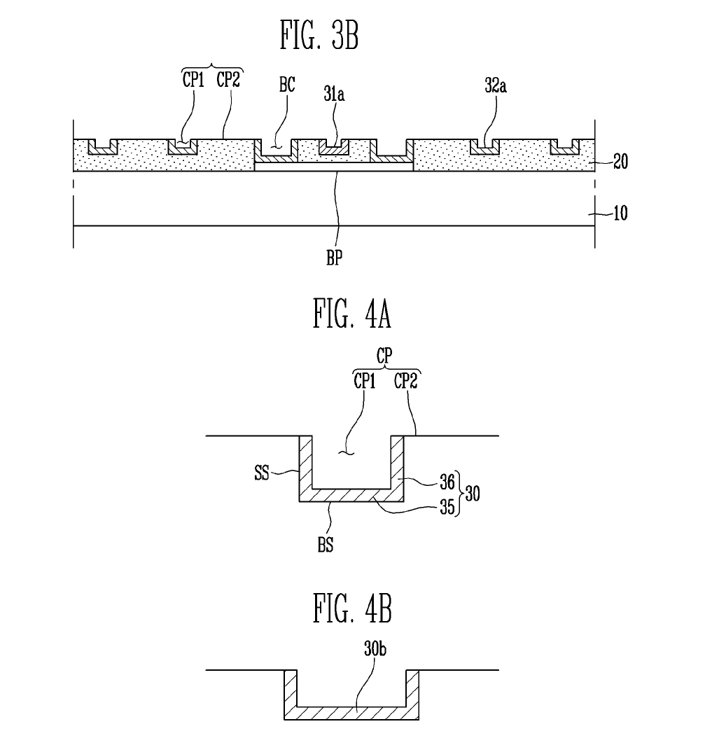

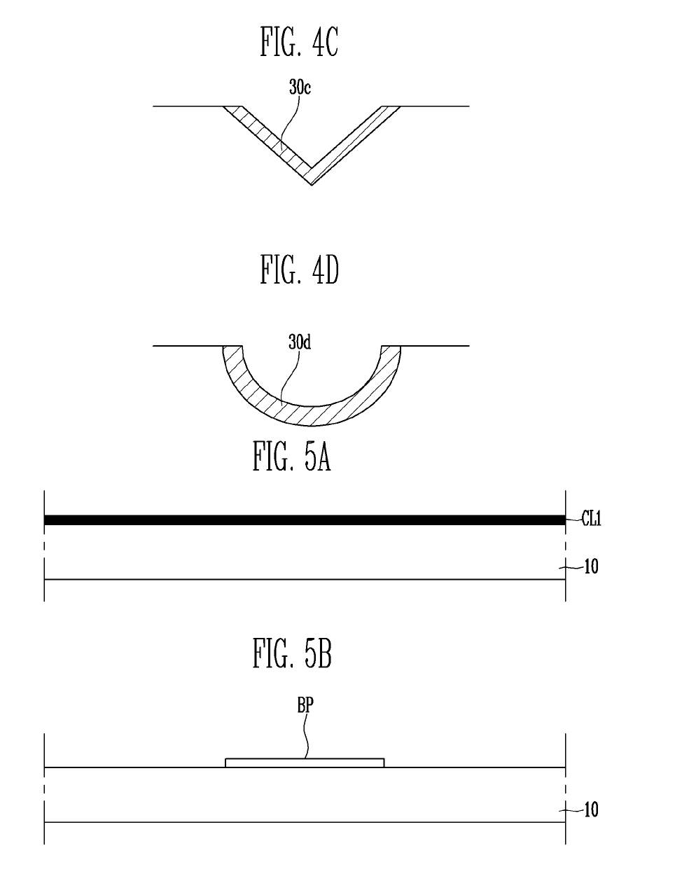

In exemplary embodiments, the insulating layer 20 may be formed on the substrate 20 and overlap the active area AA. The insulating layer 20 may include one or more concavo-convex patterns including concave portions and convex portions formed in a surface of the insulating layer 20. The concavo-convex patterns may be utilized to form the sensing electrodes 30. It is noted that the concave portions may overlap the sensing electrodes 30. The concavo-convex patterns are described in more detail with reference to FIGS. 3A and 3B.

The sensing electrodes 30 may be formed on the insulating layer 20. In this manner, the sensing electrodes 30 may be distributed and arranged in the active area AA. The sensing electrodes 30 may include first sensing electrodes 31 and second sensing electrodes 32, which may be electrically connected along different directions. For instance, the first sensing electrodes 31 may be formed of lines electrically connected along a first direction D1. The second sensing electrodes 21 may be formed of lines electrically connected along a second direction D2 intersecting the first direction D1. That is, the first sensing electrodes 31 and the second sensing electrodes 32 may be alternately disposed with one another and connected in different directions. For example, the first sensing electrodes 31 may be formed and connected in a row direction (or horizontal direction), such that row lines of the first sensing electrodes 31 are respectively connected to at least some of the outer lines 40. The second sensing electrodes 32 may be formed and connected in a column direction (or vertical direction), such that column lines of the second sensing electrodes 32 are respectively connected to other ones of the outer lines 40.

Although the first sensing electrodes 31 and the second sensing electrodes 31 have been described in the aforementioned manner, it is contemplated that the first sensing electrodes 31 and the second sensing electrodes 32 may be formed in different layers on the insulating layer 20. For example, the first sensing electrodes 31 and the second sensing electrodes 32 may be respectively formed on respective insulating layers 20 “sandwiching” the substrate 10 disposed therebetween. That is, the substrate 10 may be disposed on a first, underlying insulating layer 20 and a second, overlying insulating layer 20 may be disposed on the substrate 10. Alternatively (or additionally), the first sensing electrodes 31 and the second sensing electrodes 32 may be respectively formed on insulating layers formed on surfaces of different substrates, which may be disposed opposite one another.

As seen in FIG. 1, the sensing electrodes 30 may be made of any suitable material and may be patterned in respective diamond shapes; however, it is contemplated that the sensing electrodes 30 may form any suitable geometric shape. That is, the material and/or shape of the first sensing electrodes 31 and the second sensing electrodes 32 may be variously modified.

In exemplary embodiments, the first sensing electrodes 31 and the second sensing electrodes 32 may form metal mesh patterns including fine metal lines. That is, the first sensing electrodes 31 and the second sensing electrodes 32 may have a mesh structure in which linear electrodes intersect one another, as opposed to conventional surface electrodes. In this manner, light transmitted from an underlying display panel may pass through apertures between the intersecting liner electrodes, which may increase the transparency of the touch screen panel. To this end, it is noted that although the linear electrodes are shown intersecting at right angles, it is also contemplated that the linear electrodes may intersect at any other angle(s). For example, the linear electrodes may diagonally cross (or overlap) each other at actuate or obtuse angles.

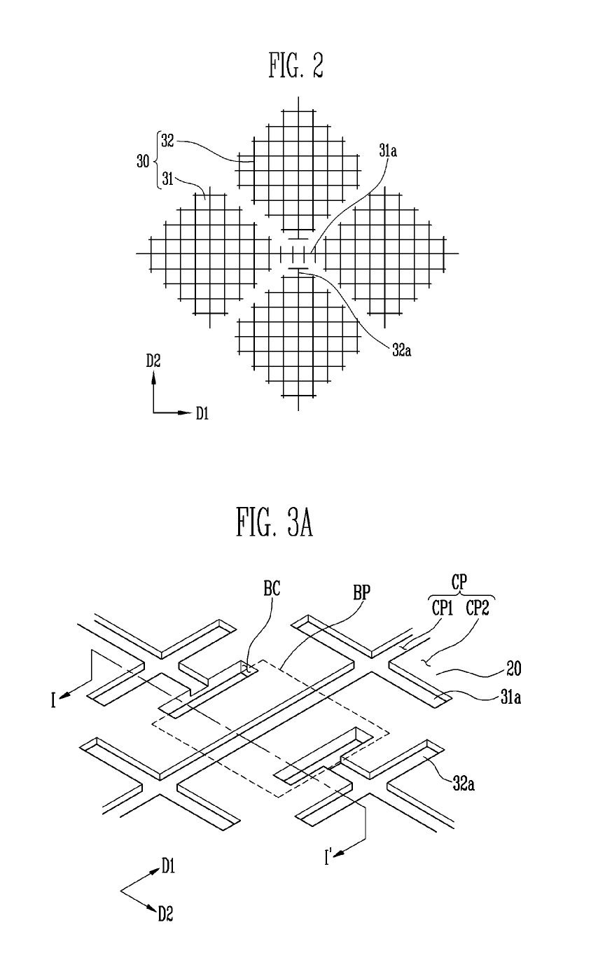

According to exemplary embodiments, the sensing electrodes 30 may be formed of any suitable transparent conductive material, such as aluminum zinc oxide (AZO), gallium zinc oxide (GZO), indium tin oxide (ITO), indium zinc oxide (IZO), etc. It is also contemplated that one or more conductive polymers (ICP) may be utilized, such as, for example, polyaniline, poly(3,4-ethylenedioxythiophene)poly(styrenesulfonate) (PEDOT:PSS), etc. To this end, the sensing electrodes may be formed of a carbon nano tube (CNT) material, transparent ink, e.g., a silver (Ag), copper (Cu), etc., transparent ink, and/or the like. As such, light may pass through the sensing electrodes 30 to increase the transparency of the touch screen panel. It is noted that the sensing electrodes 30 are described in more detail in association with FIG. 2.

The outer lines 40 may connect the first sensing electrodes 31 and the second sensing electrodes 32 to a driving circuit, e.g., an external driving circuit, (not shown) for each line longitudinally extending in the active area AA in either the first direction D1 or the second direction D2. For example, the outer lines 40 may be respectively connected electrically to the row lines of the first sensing electrodes 31 and the column lines of the second sensing electrodes 32 to connect the first sensing electrodes 31 and the second sensing electrodes 32 to the driving circuit. The driving circuit may be a position detecting circuit.

In exemplary embodiments, the outer lines 40 may be disposed in association with the non-active area NA (e.g., an outer portion of the touch screen panel) to avoid the active area AA in which an image may be displayed. The outer lines 40 may be formed of any suitable material, which may be transparent, translucent, or opaque. For example, the outer lines 40 may be formed of a transparent electrode material used to form the sensing electrodes 30 or may be formed of a low-resistance metallic material, such as, for instance, molybdenum (Mo), silver (Ag), titanium (Ti), copper (Cu), aluminum (Al), Mo/Al/Mo, etc. In this manner, it is contemplated that the outer lines 40 may include one or more layers of materials, which may include one or more different materials.

According to exemplary embodiments, the touch screen panel may be considered a capacitive-type touch screen panel. In this manner, if a contact object, such as a finger, stylus, etc., comes in contact (or close contact) with the touch screen panel, a change in capacitance at the contact (or near contact) position may be transferred from one or more sensing electrodes 30 to the driving circuit via one or more of the outer lines 40. The change in capacitance may be converted into one or more electrical signals by, for example, X-direction and Y-direction input processing circuits (not shown). As such, the contact or near contact position may be detected.

FIG. 2 is a partial enlarged view of the sensing electrodes of FIG. 1, according to exemplary embodiments. FIG. 3A is an enlarged perspective view of connecting portions of the sensing electrodes of FIG. 2, according to exemplary embodiments. FIG. 3B is a sectional view of the connecting portions taken along sectional line I-I′ of FIG. 3A.

For descriptive and illustrative convenience, two adjacent first sensing electrodes 31 and two adjacent second sensing electrodes 32 are shown in FIG. 2. It is noted, however, that the touch screen panel may include the structure of FIG. 2 in a repetitively disposed manner in the active area AA.

Referring to FIGS. 2, 3A, and 3B, the first sensing electrodes 31 and the second sensing electrodes 32 may be mesh structures in which linear electrodes intersect each other at, for example, right (or substantially right) angles. The first sensing electrodes 31 may be connected along the first direction D1 via a first connecting portion 31a. The second sensing electrodes 32 may be mesh structures (or patterns) separated between the first sensing electrodes 31. In this manner, the separated patterns may be electrically connected via a bridge pattern BP.

According to exemplary embodiments, the first sensing electrodes 31 may be patterns separated between the second sensing electrodes 32. In this manner, the separated patterns of the first sensing electrodes 31 may be connected to each line along the first direction D1 via a bridge pattern BP; however, this is optional. It is noted that FIGS. 2, 3A, and 3B, are described in association with an example in which the patterns corresponding to the second sensing electrodes 32 are separated patterns connected via bridge patterns BP.

In exemplary embodiments, the bridge pattern BP may be patterned on the substrate 10 to overlap the second connecting portions 32a. It is also contemplated that the insulating layer 20 may be formed on the substrate 10 having the bridge pattern BP formed therein. As such, a concavo-convex pattern CP including a concave portion CP1 and a convex portion CP2 may be patterned in the insulating layer 20. In this manner, the concave portions CP1 may correspond to trenches formed in the insulating layer 20 and the convex portions CP2 may correspond to portions of the insulating layer 20 separating adjacent trenches. In this manner, individual trenches may include one or more bounding surfaces defining a cross-section thereof. It is also noted that the insulating layer 20 may include bridge connecting portions BC configured to respectively expose end portions of the bridge pattern BP via partial openings (e.g., trenches) in the insulating layer 20. To this end, the bridge connecting portions BC may be patterned including the concavo-convex pattern CP previously described.

According to exemplary embodiments, the sensing electrodes 30 are formed in the insulating layer 20, and, thereby, not formed directly on the substrate 10. In this manner, the sensing electrodes 30 may have a shape corresponding to the concave portion CP1 of the concavo-convex pattern CP. That is, the sensing electrodes 30 may be formed to cover the internal surfaces of the concave portion CP1 with a determined thickness.

As seen in FIGS. 3A and 3B, the second connecting portions 32a may be positioned at end portions of adjacent second sensing electrodes 32 among the second sensing electrodes 32 that are separated from each other with a first connecting portion 31a passing between the two, separated second connecting portions 32a. At least a portion of the two, separated second connecting portions 32a may overlap at least respective portions of the bridge pattern BP. In this manner, exposed portions of the bridge pattern BP may contact the second connecting portions 32a via the bridge connecting portions BC formed in the insulating layer 20.

According to exemplary embodiments, the active area AA is transparent to enable an image from a display panel to be viewed through the touch sensing panel. As such, the sensing electrodes 30 and the bridge pattern BP may be formed of any suitable transparent electrode material or an opaque low-resistance metal material formed as described above. In this manner, the widths, thicknesses, and/or lengths of the sensing electrodes 30 and the bridge pattern BP may be adjusted so that the visualization of the sensing electrodes 30 and the bridge pattern BP is prevented (or at least reduced). For instance, since the sensing electrodes 30 may be configured with fine linear electrodes disposed in mesh structures, the sensing electrodes 30 may be formed of an opaque metal material, but enable a sufficient level of transparency to allow images from an underlying display device to be seen. It is noted that the width of the opaque metal material may be relatively very narrow as compared to the length to further prevent (or at least reduce) the potential visualization of the sensing electrodes 30.

According to exemplary embodiments, the insulating layer 20 including the concavo-convex pattern CP may be formed on the substrate 10 with the sensing electrode 30 formed in the concave portion CP1 of the concavo-convex pattern CP to enable the insulating layer 20 to protect the sensing electrodes 30. This may prevent damage of the sensing electrodes 30. It is also contemplated that a second insulating layer (not shown) may be formed on the sensing electrodes 30 and the insulating layer 20 in order to, for example, even further protect the sensing electrodes 30.

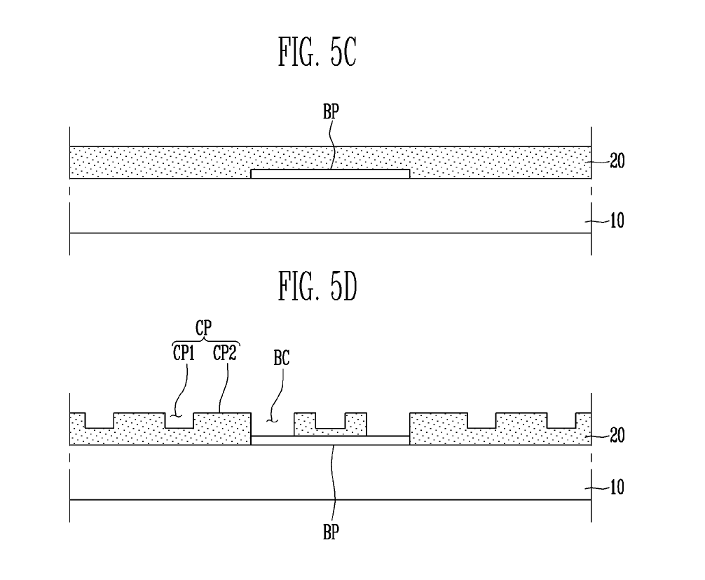

FIGS. 4A to 4D are respective sectional views of various concavo-convex patterns, according to exemplary embodiments.

Referring to FIGS. 4A to 4D, the concavo-convex pattern CP includes a concave portion CP1 and a convex portion CP2. The convex portion CP2 corresponds to an upper surface of the insulating layer 20 and the concave portion CP1 correspond to a region in which the thickness of the insulating layer 20 is decreased by removing a portion of the insulating layer 20, e.g., forming a trench in the insulating layer 20. The concave portion CP1 may include one or more bounding surfaces, e.g., at least one of a bottom surface BS, which may be parallel (or substantially parallel) to the substrate 10 and a side surface SS extended in a direction intersecting the bottom surface BS.

According to exemplary embodiments, the sensing electrode 30 is formed based on the shape of the concave portion CP1 of the concavo-convex pattern CP. As such, the sensing electrode 30 may include a bottom surface portion 35 and a side surface portion 36 respectively corresponding to the bottom surface BS and the side surface SS of the concave portion CP1 of the concavo-convex pattern CP. The thickness and breadth of the bottom surface portion 35 may be equal (or substantially equal) to those of the side surface portion 36. In this manner, the sensing electrodes 30 may not completely fill the concave portions CP1.

As seen in FIGS. 4A and 4B, when the concave portion CP1 has a square or rectilinear shape, the sensing electrode 30 or 30b may be configured with a bottom surface portion 35 and two side surface portions 36 respectively extending from the sides of the bottom surface portion 35. As seen in FIG. 4A, the depth of the sensing electrode 30 may be increased by about three times, as compared with a flat-shaped sensing electrode having a depth equal (or substantially equal) to that of the concave portion CP1. As seen in FIG. 4B, the concave portion CP1 includes a rectangular shape. In this manner, the depth of the sensing electrode 30b is decreased and the width is increased, which enables the thickness of the insulating layer 20 to be decreased that, in turn, enables an electronic device including the touch screen panel to be formed with a thinner form factor.

It is contemplated, however, that any other suitable geometric shape may be utilized to form the convex portion CP2. For instance, as seen in FIGS. 4C and 4D, the concave portion CP may include a triangular shape or a circular (or arcuate) shape. As such, the concavo-convex pattern CP and the sensing electrode 30c or 30d may be uniformly formed including a triangular or circular shape. Again, any other suitable geometric configuration may be utilized.

According to exemplary embodiments, the sensing electrode 30 is shaped in correspondence with the shape of the concave portion CP1 of the concavo-convex pattern CP, such that the amount of material forming the sensing electrode 30 is increased. This, in turn, enables the electrical resistance of the sensing electrode 30 to decrease, and, thereby, also enables touch performance to increase.

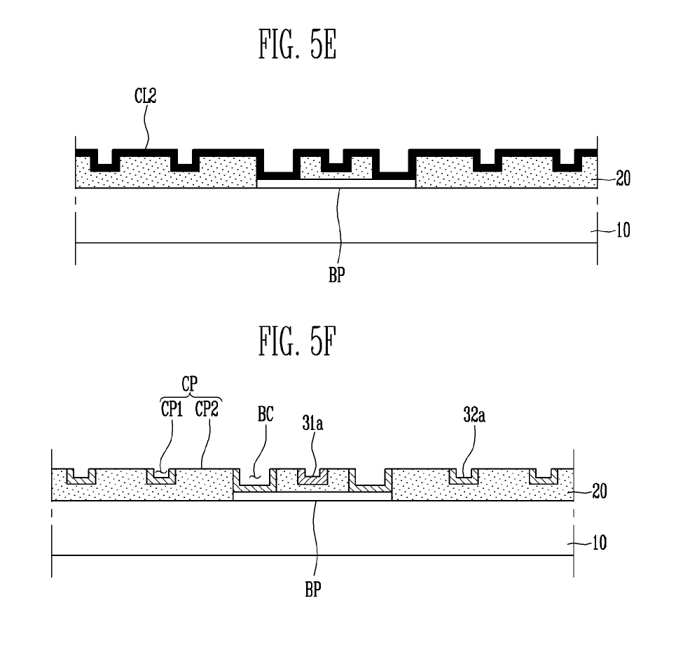

FIGS. 5A to 5F are respective sectional views of the touch screen panel of FIG. 1 at various stages of manufacture, according to exemplary embodiments.

Referring to FIGS. 5A and 5B, a first conductive layer CL1 is formed on a substrate 10. The first conductive layer CL1 is exposed and developed to form a bridge pattern BP. It is noted that the bridge pattern BP may be formed by depositing the metallic first conductive layer CL1 on the substrate 10 and then patterning the deposited first conductive layer CL1. For example, the first conductive layer CL1 may be deposited through at least one sputtering or other suitable deposition process. The at least one patterning process may include at least one photolithographic process and at least one etching process using a mask (not shown) in which a pattern corresponding to the bridge pattern BP is formed.

In exemplary embodiments, the first conductive layer CL1 may be formed of any suitable material, such as, for example, AZO, GZO, ITO, IZO, CNT, ICP, Ag transparent ink, Cu transparent ink, etc. In this manner, the sputtering process may include, for instance, physical vapor deposition (PVD), chemical vapor deposition (CVD), plasma-enhanced chemical vapor deposition (PECVD), and/or any other suitable process.

Referring to FIGS. 5C and 5D, an insulating layer 20 is formed on the substrate 10 including the bridge pattern BP formed thereon. A concavo-convex pattern CP is formed by, for example, patterning the insulating layer 20 through, for instance, photolithography, at least one imprinting process, etc. In this manner, a portion of the insulating layer 20 is opened (or otherwise removed) so that openings that may be utilized to form the bridge connecting portions BC may be respectively formed to expose end portions of the bridge pattern BP.

According to exemplary embodiments, the concavo-convex pattern CP and the bridge connecting portion BC may be formed by exposing, developing, and etching the insulating layer 20 using at least one mask (not shown) that includes a pattern corresponding to the concavo-convex pattern CP and the openings associated with the bridge connecting portions BC. It is also contemplated that the concavo-convex pattern CP and the openings corresponding to the bridge connecting portions BC may be formed by imprinting the insulating layer 20 using a hard stamp (not shown) in which a pattern corresponding to the concavo-convex pattern CP and the openings associated with the bridge connecting portion BC is formed. As can be appreciated, the imprinting process may include forming a pattern by pressing a hard stamp on the insulating layer 20 to remove (or displace) material in the openings corresponding to the bridge connecting portions BC and the concave portions CP1. As such, the imprinting process may be simpler than the photolithography and etching processes.

Referring to FIGS. 5E and 5F, a second conductive layer CL2 is formed on the insulating layer 20 including the concavo-convex pattern CP and the openings corresponding to the bridge connecting portions. In this manner, the portions of the second conductive layer CL2 positioned on the convex portion CP2 of the concavo-convex pattern CP is selectively removed to form the sensing electrodes 30. That is, the sensing electrodes 30 may be formed by depositing the metallic second conductive layer CL2 on the insulating layer 20 and patterning portions of the second conductive layer CL2 to selectively remove material positioned on the convex portions CP2. It is also noted that the second conductive material CL2 covering the insulating layer 20 between the bridge connecting portions BC and, for instance, the first connecting portion 31a may also be removed.

In exemplary embodiments, the second conductive layer CL2 may, for instance, be deposited through at least one of the aforementioned sputtering processes. The patterning process may include at least one photolithographic and etching process using a mask (not shown) including a pattern corresponding to the concave or convex portions CP1 or CP2. For instance, the second conductive layer CL2 may be patterned via electron beam lithography. As with the first conductive layer CP1, the second conductive layer CL2 may include any suitable material, such as, for example, AZO, GZO, ITO, IZO, CNT, ICP, Ag transparent ink, Cu transparent ink, etc. To this end, it is noted that the substrate 10 may be tilted during deposition of the second conductive layer CL2 to enable the second conductive layer CL2 to be more uniformly formed on the bottom surfaces BS and the side surfaces SS of the concavo-convex patterns CP.

According to exemplary embodiments, a touch screen panel may be formed including sensing electrodes 30 on a substrate 10. The sensing electrodes 30 may be formed of a transparent conductive material. As such, when a flexible substrate 10 is utilized, the touch screen panel may also be flexible to prevent (or otherwise reduce) the generation of cracks in, for instance, the sensing electrodes 30 due, at least in part, to potential bending or deformation of the touch screen panel, e.g., the substrate 10. In exemplary embodiments, substrate 10 is sufficiently flexible to increase the durability of the touch screen panel, and, thereby, prevent (or otherwise reduce) driving failures caused, at least in part, by cracks that may otherwise be formed in the sensing electrodes 30.

In exemplary embodiments, the touch screen panel further includes an insulating layer 20 including a concavo-convex pattern CP formed on substrate 10. The sensing electrodes 30 may be formed in a concave portion CP1 of the concavo-convex pattern CP to enable the insulating layer 20 to protect the sensing electrodes 30. This further prevents (or otherwise reduces) the potential for damage to the sensing electrodes 30. Moreover, the sensing electrodes 30 may be shaped in correspondence with the concave portions CP1 to enable more material to be utilized to form the sensing electrodes 30, but still maintain a thin, fine electrode structure with sufficient transparency to promote the display of images through the touch screen panel. To this end, electrical resistance may be decreased and touch performance may be improved.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A method of fabricating a touch screen panel, the method comprising:
forming an insulating layer on a substrate;
forming a pattern in the insulating layer, the pattern comprising concave portions and convex portions; and
forming sensing electrodes in at least a portion of the concave portions.

2. The method of claim 1, wherein each of the concave portions comprises at least one of a bottom surface substantially parallel to a surface of the substrate and a side surface extending in a direction intersecting the surface of the substrate.

3. The method of claim 2, wherein each of the sensing electrodes comprises a bottom surface portion and a side surface portion respectively corresponding to the bottom surface of a concave portion and the side surface of the concave portion.

4. The method of claim 3, wherein the thickness and length of the bottom surface portion are substantially equal to the thickness and length of the side surface portion.

5. The method of claim 1, wherein the sensing electrodes comprise:
first sensing electrodes disposed in an active area of the substrate, the first sensing electrodes being arranged in a first direction; and
second sensing electrodes disposed in the active area, the second sensing electrodes being arranged in a second direction intersecting the first direction.

6. The method of claim 5, wherein the sensing electrodes comprise mesh structures.

7. The method of claim 5, further comprising:
forming bridge patterns electrically connecting adjacent second sensing electrodes.

8. The method of claim 7, wherein the insulating layer is formed on the bridge patterns, the bridge patterns being disposed between the insulating layer and the substrate.

9. The method of claim 7, wherein the pattern in the insulating layer comprises trenches exposing end portions of the bridge pattern.

10. The method of claim 9, wherein bridge connecting portions are disposed in the trenches and electrically connect adjacent second sensing electrodes via corresponding bridge patterns.

11. The method of claim 7, wherein forming the bridge patterns comprises:
forming a conductive layer on the substrate; and
patterning the conductive layer to form the bridge patterns,
wherein connecting portions of adjacent second sensing electrodes at least partially overlap a corresponding bridge pattern disposed therebetween.

12. The method of claim 1, wherein forming the pattern comprises:
performing at least one of a photolithographic process and a imprinting process.

13. The method of claim 1, wherein forming the sensing electrodes comprises:
forming a conductive layer on the insulating layer comprising the pattern; and
removing portions of the conductive layer disposed on the convex portions,
wherein remaining portions of the conductive layer disposed on the concave portions correspond to the sensing electrodes.

14. The method of claim 13, wherein:
forming the conductive layer comprises sputtering a material on the insulating layer; and
removing the portions of the conductive layer comprises performing electron beam lithography.

15. The method of claim 1, wherein the substrate corresponds to a thin-film of at least one of polyethylene terephthalate (PET), polyimide (PI), polyethylene (PE), polycarbonate (PC), polyamide (PA), poly(methyl methacrylate) (PMMA), triacetylcellulose (TAC), and polyethersulfone (PES).

16. A touch screen panel, comprising:
a flexible substrate;
an insulating layer disposed on the flexible substrate, the insulating layer comprising a pattern of trenches formed therein; and
sensing electrodes at least partially formed in the trenches.

17. The touch screen panel of claim 16, wherein:
the trenches respectively comprise one or more bounding surfaces; and
each sensing electrode is disposed on each of the one or more bounding surfaces of a corresponding trench.

18. The touch screen panel of claim 17, wherein the one or more bounding surfaces of each trench defines one of an ovular cross-section, a triangular cross-section, and a rectilinear cross-section.

19. The touch screen panel of claim 17, wherein the thickness of each sensing electrode on each of the one or more bounding surfaces is substantially the same.

20. The touch screen panel of claim 16, wherein each of the sensing electrodes comprises fine sensing electrode lines forming a corresponding mesh structure.
